(19) United States
(12) Patent Application Publication
(10) Pub. No.: US 2023/0177226 A1
(43) Pub. Date: Jun. 8, 2023

(54) INTERIOR LAYOUT DEVICE FOR PROVIDING ANALYSIS OF SPACE USAGE RATE AND OPERATION METHOD THEREOF

(71) Applicant: ARCHIDRAW. INC., Seoul (KR)

(72) Inventors: Jusung LEE, Gwangmyeong-si (KR); Jong Seon HONG, Seoul (KR); Jeppe Bo ANDERSEN, Seoul (KR)

(21) Appl. No.: 17/758,064

(22) PCT Filed: Nov. 27, 2020
(86) PCT No.: PCT/KR2020/017204

§ 371 Date: Jan. 18, 2023

(30) Foreign Application Priority Data
Dec. 27, 2019 (KR) 10-2019-0175995

(51) Int. Cl. G06F 30/13; G06T 11/20; G06T 11/00

(52) U.S. Cl. CPC G06F 30/13; G06T 11/001; G06T 11/206; G06T 2210/04

(57) ABSTRACT

An operation method of an interior layout device according to an embodiment of the present invention comprises the steps of: obtaining interior layout information and indoor structure information of a user; obtaining an indoor plan view graph from the indoor structure information and the interior layout information; processing a space usage rate analysis using the indoor plan view graph; generating an analysis interface in which color information is mapped to the indoor plan view graph according to the space usage rate analysis; and outputting the analysis interface.

### TECHNICAL FIELD

The present invention relates to an interior layout automation method and a device therefor. More specifically, the present invention relates to an interior layout device for providing a space use rate analysis, and an operation method thereof.

### BACKGROUND ART

Generally, in designing drawings of a building, a CAD program is installed in a personal computer, a notebook computer, or the like, and drawings are created and design results are produced using a device such as a mouse, a tablet, or the like.

However, as society develops from an industrial society to an information society, virtual reality techniques, which can replace functions of model houses or the like by providing three-dimensional modeling results themselves, rather than drawings, to users more easily in the form of user experience, are emerging.

For example, Virtual Reality (VR) or Augmented Reality (AR) is created for the purpose of a virtual tour inside a building (house, apartment, office, hospital, church, or the like) or a simulation of interior or furniture arrangement (or indoor simulation), and various methods are proposed to provide a user with simulated environments and situations to interact therebetween based thereon.

To this end, a method of generating three-dimensional data of a building or an indoor structure manually or using a 3D scanner in advance and providing virtual reality based thereon may be used. However, this method is difficult to implement as a three-dimensional construction modeling process by estimation from scan information or drawings is required, and there is a problem in that the accuracy is lowered due to the limitations in the data processing and manual works.

In addition, when a user desires to design an interior through furniture or objects randomly arranged in an indoor structure, the furniture or objects should be precisely installed and harmoniously arranged in a three-dimensional space, but this work is very difficult when the user is not a professional 3D designer.

Therefore, with only the current techniques, professional manpower is required to generate structured indoor information and interior of a building in reality, and the time and cost are excessively required.

Meanwhile, design of the interior information and interior layout determines utilization of space. However, it is very difficult to understand the space utilization and visual expression without a professional analysis based on a manual work that is conducted with the help of an architectural analyst.

Accordingly, it is required to provide a function interface that allows a user to easily design an indoor structure and an interior layout while considering the effect on space utilization without a professional analysis work.

### DISCLOSURE OF INVENTION

### Technical Problem

Therefore, the present invention has been made in view of the above problems, and an object of the present invention is to allow a user to intuitively and conveniently generate space and interior design information by automatically processing, on the basis of a user style, spaces and interiors arranged on the indoor structure information without requiring a separate precise design or a professional work of an expert, and particularly provide a device and an operating method thereof, which can provide an indoor space and interior design of abundant and various forms, together with user convenience, by analyzing the style of input video information to make it possible to design indoor spaces and interiors of a type similar thereto.

In addition, another object of the present invention is to provide a function interface which provides, without a professional analysis based on a manual work, visual expression of space utilization and a use rate thereof made by spaces and interiors, and facilitates understanding of the space utilization and use rate and design of a layout thereof, by providing an automated space use rate analysis function based on a space structure, interior arrangement, and prediction of user’s movement, and a visualization interface that visualizes the analysis function.

### Technical Solution

To accomplish the above object, according to one aspect of the present invention, there is provided an operation method of an interior layout device, the method comprising the steps of: obtaining indoor structure information and interior layout information of a user; obtaining an indoor floor plan graph from the indoor structure information and the interior layout information; processing a space use rate analysis using the indoor floor plan graph; generating an analysis interface in which color information is mapped to the indoor floor plan graph according to the space use rate analysis; and outputting the analysis interface.

According to another aspect of the present invention, there is provided an interior layout device comprising: a space use rate analysis unit for obtaining indoor structure information and interior layout information of a user, obtaining an indoor floor plan graph from the indoor structure information and the interior layout information, processing a space use rate analysis using the indoor floor plan graph, and generating an analysis interface in which color information is mapped to the indoor floor plan graph according to the space use rate analysis; and an interface output unit for outputting the analysis interface.

Meanwhile, the method according to an embodiment of the present invention for solving the problems described above includes a program for executing the method in a computer and a recording medium in which the program is recorded.

### Advantageous Effects

According to an embodiment of the present invention, a user is allowed to intuitively and conveniently generate space and interior design information by automatically processing, on the basis of a user style, spaces and interiors arranged on the indoor structure information without requiring a separate precise design or a professional work of an expert.

In addition, according to an embodiment of the present invention, it is possible to provide a device and an operating method thereof, which can provide an indoor space and interior design of abundant and various forms, together with user convenience, by analyzing the style of input video information to make it possible to design indoor spaces and interiors of a type similar thereto.

In addition, the present invention may provide a function interface which provides, without a professional analysis based on a manual work, visual expression of space utilization and a use rate thereof made by spaces and interiors, and facilitates understanding of the space utilization and use rate and design of a layout thereof, by providing an automated space use rate analysis function based on a space structure, interior arrangement, and prediction of user’s movement, and a visualization interface that visualizes the analysis function.

### BRIEF DESCRIPTION OF THE DRAWINGS

FIG. 1 is a block diagram showing an interior layout device according to an embodiment of the present invention.

FIG. 2 is a flowchart illustrating an interior layout method according to an embodiment of the present invention.

FIG. 3 is a flowchart illustrating an iteration process of generating an interior layout according to an embodiment of the present invention.

FIG. 4 is a view showing cost efficiency with respect to the number of iterations of an iteration process of generating an interior layout according to an embodiment of the present invention.

FIGS. 5 and 6 are views showing an indoor structure information interface output from an interior layout device as a method according to an embodiment of the present invention is performed.

FIG. 7 is a block diagram showing a space use rate analysis unit according to an embodiment of the present invention in more detail.

FIG. 8 is a flowchart illustrating the operation of a space use rate analysis unit according to an embodiment of the present invention.

FIGS. 9 to 10 are exemplary views showing an analysis interface including visualized space use rate analysis information according to an embodiment of the present invention.

### BEST MODE FOR CARRYING OUT THE INVENTION

Hereinafter, only the principles of the present invention will be exemplified. Therefore, although not clearly described or shown in this specification, those skilled in the art will be able to implement the principles of the present invention and invent various devices included in the spirit and scope of the present invention. In addition, it should be understood that all conditional terms and embodiments listed in this specification are, in principle, clearly intended only for the purpose of understanding the concept of present invention, and not limited to the embodiments and states specially listed as such.

In addition, it should be understood that all detailed descriptions listing specific embodiments, as well as the principles, aspects, and embodiments of the present invention, are intended to include structural and functional equivalents of such matters. In addition, it should be understood that such equivalents include equivalents that will developed in the future, as well as currently known equivalents, i.e., all devices invented to perform the same function regardless of the structure.

Therefore, for example, the block diagrams in the specification should be understood as expressing the conceptual viewpoints of illustrative circuits that embody the principles of the present invention. Similarly, all flowcharts, state transition diagrams, pseudo code, and the like may be practically embodied on computer-readable media, and it should be understood that regardless of whether or not a computer or processor is explicitly shown, they show various processes performed by the computer or processor.

Functions of various elements shown in the figures including a processor or functional blocks expressed as a concept similar thereto may be provided by the use of hardware having an ability to execute software in association with appropriate software, as well as dedicated hardware. When provided by a processor, the functions may be provided by a single dedicated processor, a single shared processor, or a plurality of individual processors, some of which may be shared.

In addition, explicit use of the terms presented as processors, controls, or concepts similar thereto should not be interpreted by exclusively quoting hardware having an ability of executing software, and should be understood to implicitly include, without limitation, digital signal processor (DSP) hardware, and ROM (ROM), RAM (RAM) and non-volatile memory for storing software. Other known common hardware may also be included.

In the claims of this specification, components expressed as a means for performing the functions described in the detailed description are intended to include, for example, combinations of circuit elements performing the functions or all methods that perform the functions including all forms of software such as firmware/microcode and the like, and are combined with suitable circuits for executing the software to perform the functions. Since the present invention defined by the claims is combined with the functions provided by the various listed means and combined with the method requested by the claims, it should be understood that any means capable of providing the functions are equivalent to those grasped from the specification.

The above objects, features and advantages will become more apparent through the following detailed description related to the accompanying drawings, and accordingly, those skilled in the art may easily implement the technical spirit of the present invention. In addition, when it is determined in describing the present invention that the detailed description of a known technique related to the present invention may unnecessarily obscure the gist of the present invention, the detailed description thereof will be omitted.

Hereinafter, a preferred embodiment according to the present invention will be described in detail with reference to the accompanying drawings.

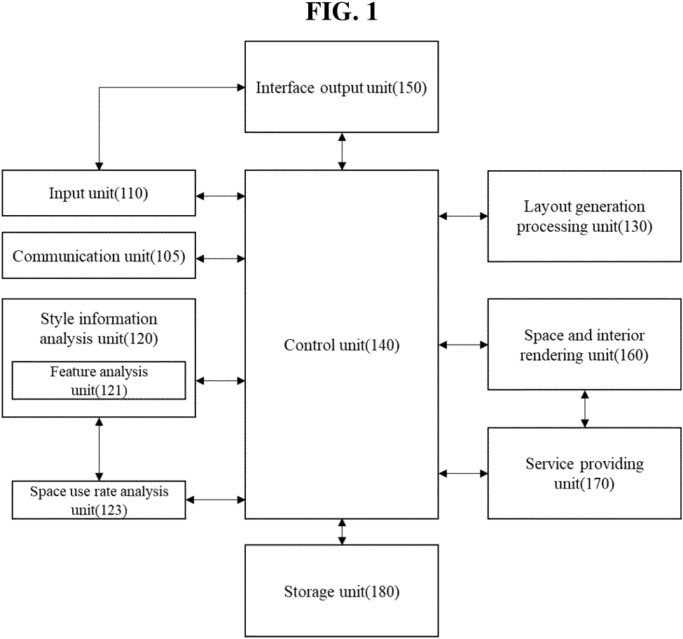

FIG. 1 is a block diagram showing an interior layout device according to an embodiment of the present invention.

The interior layout device 100 described in this specification may include, for example, various electronic devices such as a cellular phone, a smart phone, a computer, a laptop computer, a digital broadcasting terminal, a personal digital assistant (PDA), a portable multimedia player (PMP), a navigator, a virtual reality device, and the like operating according to a user input.

In addition, a program or an application for executing the methods according to an embodiment of the present invention may be installed and operate in the interior layout device 100.

Accordingly, the interior layout device 100 according to an embodiment of the present invention may provide an interface for generating and editing indoor structure information, and the indoor structure information generated according to an embodiment of the present invention may be stored in the interior layout device 100, or uploaded to a separate server (not shown) or the like and managed according to user information.

Here, the indoor structure information may include two-dimensional or three-dimensional building floor plan information, and may include structure information that can be used for indoor interior simulation or the like as three-dimensional modeling information is matched. In addition, the indoor structure information may include one or more walls and connection information of the walls, and may form one or more closed spaces.

The interior layout device 100 may be provided with a distance measurement sensor and an angle measurement sensor inside or outside to facilitate generation of the indoor structure information, and may determine the indoor structure information according to a user input.

In addition, the interior layout device 100 may acquire previously stored or uploaded indoor structure information in correspondence to the user information, and may provide an interior layout editing function corresponding to the acquired indoor structure information.

Particularly, according to an embodiment of the present invention, the interior layout device 100 may provide an interior layout automation function capable of automatically processing arrangement of furniture interiors and design of spaces according to analysis of user style information in correspondence to the indoor structure information of the user.

More specifically, when the indoor structure information of a user is acquired, the interior layout device 100 according to an embodiment of the present invention may generate interior layout automation information including a space layout and an interior arrangement design determined in correspondence to the indoor structure information, and output the interior layout automation information according to processing of the style information analysis corresponding to the user.

The interior layout device 100 may use the automation information output as described above to perform interior rendering processing on the indoor structure information, and the rendered indoor structure information may be output through an indoor structure information interface of the interior layout device 100.

Accordingly, the indoor structure information, in which the interior furniture and space layout design is automated, may be used for editing, sharing, and storing information according to a user input, and furthermore, may be used for indoor simulation and as a function for linking purchase of each arranged furniture.

For example, the interior layout device 100 may perform a function of visualizing a three-dimensional space similar to reality on a virtual space displayed on a display or the like of the interior layout device 100, and arranging three-dimensional objects based on the interior layout automation information on the indoor simulation graphic based on the indoor structure information. Accordingly, the indoor simulation may be preferably used for a floor plan that simulates furniture and the like that will be arranged in a room, and a floor plan application may be included in an application that provides the indoor simulation.

Accordingly, the interior layout device 100 according to an embodiment of the present invention may generate an interior arrangement and space layout design according to a user style on the indoor structure information according to a user input, and accordingly, the user may be provided with and edit a space layout and furniture arrangement of a style desired by the user, without a separate precise design or a design work, to construct two-dimensional and three-dimensional indoor structure information in various ways. Accordingly, it is possible to provide an interior layout device 100 and an operating method thereof, which can enhance user convenience and diversity of indoor interior configurations.

To this end, a separate server device may store the predetermined application that can be installed in the interior layout device 100 and information needed to provide the indoor simulation, and provide user registration and indoor structure information management for the user of the interior layout device 100. The interior layout device 100 may download and install the application from the server device.

In addition, at least some components of the interior layout device 100 according to an embodiment of the present invention may be implemented in a separate server device located at a remote location for the sake of processing efficiency.

For example, the style information analysis and layout generation function of the interior layout device 100 according to an embodiment of the present invention may be performed in a remote server device, and the interior layout device 100 may receive an execution result, render spaces and interiors, and provide a service thereof. Accordingly, the interior layout device 100 according to an embodiment of the present invention may be a single device or a combined device in which at least some functions are processed in other devices.

Detailed components of each device for implementing this concept will be described in more detail.

Referring to FIG. 1 again, the interior layout device 100 includes a communication unit 105, an input unit 110, a style information analysis unit 120, a layout generation processing unit 130, a control unit 140, an interface output unit 150, a space and interior rendering unit 160, a service providing unit 170, and a storage unit 180. Since the components shown in FIG. 1 are not indispensable, a terminal having more or fewer components may be implemented.

First, the communication unit 105 may include one or more modules that allow wireless communication between the interior layout device 100 and a wireless communication system or between the interior layout device 100 and a network in which the interior layout device 100 is located.

For example, the communication unit 105 may include a broadcast receiving module, a mobile communication module, a wireless Internet module, a short-range communication module, and a location information module. The mobile communication module transmits/receives wireless signals to and from at least one among a server device, a base station, an external terminal, and a server on a mobile communication network. The wireless Internet module refers to a module for wireless Internet access, and may be installed inside or outside the interior layout device 100. As a wireless Internet technique, a wireless LAN (WLAN) (Wi-Fi), a wireless broadband (Wibro), a World Interoperability for Microwave Access (Wimax), a HighSpeed Downlink Packet Access (HSDPA), and the like may be used.

The short-range communication module refers to a module for short-range communication. Bluetooth, Radio Frequency Identification (RFID), Infrared Data Association (IrDA), Ultra-Wideband (UWB), ZigBee, or the like may be used as the short-range communication techniques.

The location information module is a module for acquiring the location of a terminal, and a representative example thereof is a Global Position System (GPS) module.

In addition, for example, the communication unit 105 may upload completed indoor structure information and interior layout information to the server device, or may receive registered indoor structure information or interior layout information from the server device in correspondence to user information. Here, the interior layout information may be interior layout information acquired from input video information or may include interior layout automation information processed by the server device.

The input unit 110 generates input data for the user to control the operation of the terminal. The user input unit 110 may include at least one among a keypad, a dome switch, a touch screen (resistive/capacitive), a jog wheel, and a jog switch.

The style information analysis unit 120 analyzes style information of the user, and transmits the analyzed style information to the layout generation processing unit 130. To this end, the style information analysis unit 120 may include a feature analysis unit 121.

First, the style information analysis unit 120 may receive style-related information corresponding to the user through the input unit 110, and the input style-related information may be transmitted to the feature analysis unit 121.

More specifically, the style-related information may indicate interior information preferred by the user according to a user input, and the style information analysis unit 120 may analyze the interior information preferred by the user to generate user style information that will be transmitted to the layout generation processing unit 130.

Here, as a specific factor that indicates the interior information preferred by the user, the style-related information may include interior video information that the user desires to build in a similar form, or may include information on the style pattern of the user that the user himself or herself selects and inputs.

For example, in order to apply a space interior layout of a form similar to that of a space interior of a specific video or image to his or her indoor structure information, the user may input specific video or image information, or input interior picture or video information confirmed through a social network service or its social network service link information as the style-related information.

In addition, for example, a user may input preferred style information of an interior to be automatically arranged in his or her indoor structure information, as the style-related information. For example, the user may input various style information such as the size, arrangement, and matching style of furniture or the size, shape, quantity, and type of a space through the input unit 110.

The feature analysis unit 121 may acquire style information of the user by analyzing the style-related information, and the acquired style information may be transmitted to the layout generation processing unit 130. Here, the user style information may include feature variable information for the layout generation iteration processing of the layout generation processing unit 130.

More specifically, for example, the feature analysis unit 121 may perform a process of generating a feature variable for generating an interior cost function based on the style information of the user.

The interior cost function is devised to determine an optimal space and interior layout by the layout generation processing unit 130, and may be used to evaluate a degree of actual arrangement of the interior according to the feature variable of an interior object set corresponding to the indoor structure information.

That is, the layout generation processing unit 130 may repeatedly iterate the interior cost function operation based on the feature variable information in order to generate an optimized space and interior layout, and the feature analysis unit 121 may perform a style information analysis corresponding to the video information or the like to acquire and provide feature variable information corresponding to the style information of the user to the layout generation processing unit 130.

The interior cost function f(x) according to the feature variable may be shown in Equation 1.

$$f \left(x\right) = {e}^{{\sum }_{i} {w}_{i} {g}_{i} \left(x\right)}$$

Here, x may denote an interior layout, gi(x) may denote an i-th feature variable operation, and wi may denote a weight value thereof. A result value of the f(x) function operation may represent the cost of layout x, and a lower cost value may represent a more realistic and natural layout.

The layout x may include one or more sets of interior feature variables, and the interior feature variable may correspond to, for example, an indoor structure, a wall, a corner, a window, a door, and a furniture object element, and each of the size, shape, type, location, and rotation values corresponding to each element may be assigned as a feature variable.

Accordingly, the total cost may be determined according to the feature variable value and a weight corresponding to each interior element, and as a result, this may mean that the total cost may be determined according to the type, arrangement, rotation, and function weight of the interior element.

In addition, for example, the feature variable may include a space layout element corresponding to an interior furniture element and normalized distance information generated to be relative thereto. The space layout element may include at least one among a wall, a corner, a door, a window, and a neighboring extra space, and the feature variable may include a normalized distance value between the space layout element and a specific interior furniture element. Accordingly, a degree of relative space between pieces of interior furniture and walls, a distance between pieces of furniture in the neighborhood, and the like may be calculated as a cost function, and this may be processed by the gi(x) function.

In addition, the weight wi may be a feature variable determined from function weight information, and may indicate importance of a specific interior element. Such weight information may be acquired from the user style information.

For example, like a chair matching a desk, matching between objects may be relatively more important than that of other furniture that does not need to be aligned with the wall. Accordingly, the feature variable according to an embodiment of the present invention may assign importance of matching according to assignment of weight information. The importance of matching may be variably assigned according to the type of an indoor structure, the type of a room, or the like, and may be generated according to a user’s selection input or generated statistically according to accumulation of data.

Meanwhile, the style information analyzed by the feature analysis unit 121 may be used to generate a space layout design function of the layout generation processing unit 130.

More specifically, the layout generation processing unit 130 may determine a space layout design function for modifying the interior cost function described above.

For example, the layout generation processing unit 130 may determine a space layout design function according to the feature variable of the style analysis information, and the space layout design function may include one or more limiting functions for modifying the interior cost function.

The function of the space layout design function is to restrictively define the rules of a space layout to increase the space use rate and meet the preference of the user, and various rules, such as i) overall movement and rotation of an interior element object, ii) movement of an interior element object to a neighboring wall, iii) rotation of an interior element object in correspondence to an arbitrary wall iv) movement of an interior element object to vicinity of another arbitrary element object, may be defined.

Particularly, the space layout design function may be generated in the form of a modification function that reduces the cost of the interior layout function. The modification function may be determined to be different according to the type of each interior element, and may be a function that reduces a cost corresponding to a single function of a single interior element.

Accordingly, the feature analysis unit 121 according to an embodiment of the present invention may include a process of generating a modification variable for generating a space layout design function based on the style information of the user, and the modification variable may be determined according to the space and interior type information.

For example, generally, the interior and space feature may be divided into two types of groups, and the first group is an associative feature between an indoor structure (room or the like) and interior furniture, and may include, for example, a distance between furniture and a nearest wall, a degree of rotation with respect to an adjacent wall, a feature of relative arrangement with respect to a door/window, and the like. The second group is an associative feature between pieces of interior furniture, and may include features such as a distance between a bed and a side table, a distance between a desk and a chair, and the like.

Although these features may be easy for a human to intuitively determine, according to operations, it is not easy to automatically process. Accordingly, the layout generation processing unit 130 according to an embodiment of the present invention may define a function that results in cost reduction as a space layout design function, and accordingly, further cost-effective space interior information may be generated through a space layout design for the space interior information determined by the primarily generated interior cost function.

In addition, the rules of each interior layout and space interior design may have a high correlation with each other. For example, a desk should be aligned with a wall, furniture should not interfere with movement of opening doors or windows, and specific pieces of furniture have a correlation of being adjacent to each other, like a desk and a chair. However, the correlation is difficult to clearly derive, and has a feature of ambiguity. For example, even some pieces of furniture considerably spaced apart from each other, like a chair and a TV, may have a correlation of distance. However, the correlation is an intuitive factor, and is difficult to model with easy by a human.

Accordingly, the layout generation processing unit 130 allows efficient, accurate, and realistic interior layout automation processing by generating such a correlation model through iterative operation of learning data, such as machine learning, performing an interior layout automation process based on a specific cost function using the generated model, and determining an optimal interior layout through the processing.

More specifically, according to a relationship learning process of the weight values applied to the interior cost function and the space layout design function determined according to the style information analysis process in correspondence to the indoor structure information, the layout generation processing unit 130 may perform an iteration process of generating optimal interior layout automation information by repeatedly generating arbitrary interior layouts.

Here, as the iteration process is performed by 1) creating arbitrary initial interior layouts, 2) determining a first layout group having a low cost based on an interior layout function corresponding thereto, 3) determining a second layout group having a low cost based on a space layout design function modifying the interior layout function, 4) determining an arbitrary third layout group, and performing steps 2) to 4) using an overall layout group combining the layout groups as an initial layout, it may include a process of repeatedly performing an iteration operation, and determining a layout having the lowest cost among the current layouts as optimal interior layout automation information according to an iteration termination operation.

Here, the iteration process may be terminated by comparing a space use rate value, which is obtained according to a space use rate analysis operation of a space use rate analysis unit 123, and a threshold value. The threshold value may be determined by a separate setting based on a user style or efficiency, and whether or not the space use rate is optimized may be determined by the threshold value.

To this end, the space use rate analysis unit 123 may perform a space use rate analysis for each layout. The space use rate analysis may take into account factors such as tolerance and density in a space, and adjacency between spaces according to movement paths, and the space use rate analysis unit 123 may perform a function of calculating a use rate when a specific layout is input and outputting the use rate to the layout generation processing unit 130.

In addition, the space use rate analysis unit 123 may be included as a component of the style information analysis unit 120. For example, the style information analyzed by the style information analysis unit 120 may include space use rate information, and accordingly, a space use rate iteration threshold that can be allowed for each user style may be set differently.

The optimal interior layout automation information may be determined through the iteration process, and the determined interior layout automation information may be transmitted to the space and interior rendering unit 160.

The rendering unit 160 may perform a space and interior rendering process by applying the interior layout automation information to the indoor structure information, and the rendered space and interior data may be output through the interface output unit 150.

In addition, the service providing unit 170 provides service functions such as space interior experience, interior editing, furniture tagging, furniture information, purchase information, and the like based on the interior layout automation information.

For example, the service providing unit 170 may acquire user service information including furniture information used for interior arrangement, a purchase link, and the like, and output the acquired user service information through the interface output unit 150.

In addition, for example, the service providing unit 170 may output a tagging interface of one or more pieces of furniture information included in a video image, in which the interior layout automation information is rendered, through the interface output unit 150, and process a service of providing the furniture information and purchase link according to a user input corresponding to the tagging interface.

Accordingly, the user may be provided with an automated interior layout service, and the user himself or herself may confirm detailed information and purchase information of the furniture that will be actually applied to his or her own indoor space.

The interface output unit 150 is for generating an output related to visual, auditory or tactile sense by providing the interface as described above, and may include a display unit, a sound output module, an alarm unit, a haptic module, and the like.

The display unit displays (outputs) information processed by the interior layout device 100. For example, when the terminal is in an indoor simulation mode, a user interface (UI) or a graphic user interface (GUI) related to the indoor simulation and floor plan is displayed. In addition, a user interface for generating indoor structure information according to an embodiment of the present invention may be displayed on the interface screen.

The display unit may include at least one among a liquid crystal display (LCD), a thin film transistor-liquid crystal display (TFT LCD), an organic light-emitting diode (OLED), a flexible display, and a 3D display.

The storage unit 180 may store programs for the operation of the control unit 140, and may temporarily store input/output data.

The storage unit 180 may include at least one type of storage medium among memory of a flash memory type, a hard disk type, a multimedia card micro type, or a card type (e.g., SD or XD memory), Random Access Memory (RAM), Static Random Access Memory (SRAM), Read-Only Memory (ROM), Electrically Erasable Programmable Read-Only Memory (EEPROM), Programmable Read-Only Memory (PROM), Magnetic Memory, a magnetic disk, and an optical disk. The interior layout device 100 may operate on the Internet in relation to a web storage that performs the storage function of the storage unit 180.

The control unit 140 generally controls the overall operation of the terminal, and performs related controls and processes for generation of indoor structure information, analysis of style information, generation of a layout, automated rendering of spaces and interiors, provision of an interface, voice call, data communication, video call, and the like.

In addition, according to a user input, the control unit 140 may store the indoor structure information on which interior automation is processed in the storage unit 180 or may process the information to be transmitted to the server device through the communication unit 105.

For example, the indoor structure information on which interior automation is processed may be matched to the user account information of the interior layout device 100, and stored and managed in a cloud server or the server device.

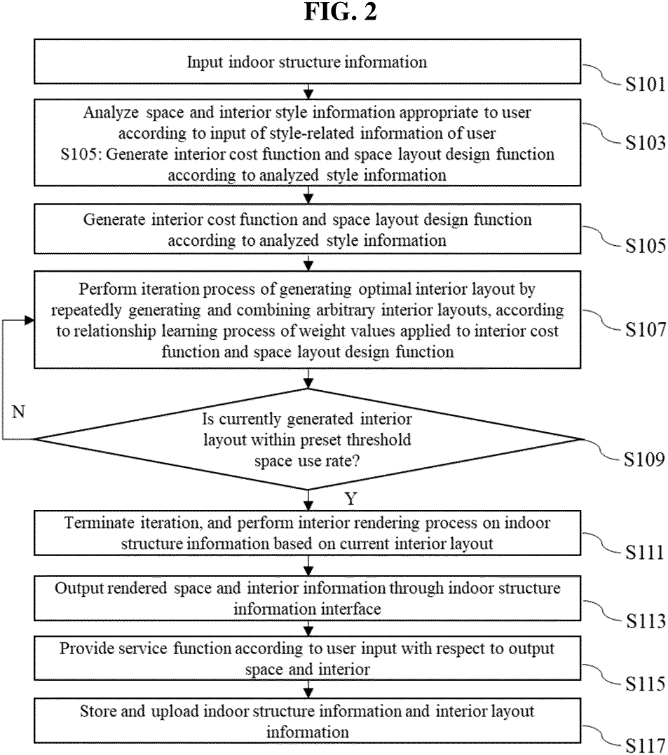

FIG. 2 is a flowchart illustrating an interior layout method according to an embodiment of the present invention.

Referring to FIG. 2, first, indoor structure information is input into the interior layout device 100 according to an embodiment of the present invention (S101).

Here, the indoor structure information may be indoor structure information acquired according to a user input in the interior layout device 100 or indoor structure information input and received from an external device, and may have a format of two-dimensional indoor floor plan information or three-dimensional indoor space structure information.

Then, the interior layout device 100 analyzes space and interior style information appropriate to the user according to input of style-related information of the user (S103).

Thereafter, the interior layout device 100 generates an interior cost function and a space layout design function modifying the interior cost function according to the analyzed style information (S105).

Next, according to a relationship learning process of the weight values applied to the interior cost function and the space layout design function, the interior layout device 100 performs an iteration process of generating an optimal interior layout by repeatedly generating arbitrary interior layouts (S107).

Then, the interior layout device 100 determines whether the currently generated interior layout is within a preset threshold space use rate (S109), and when it is within the threshold space use rate, the interior layout device 100 terminates the iteration, and performs an interior rendering process on the indoor structure information based on the current interior layout (S111).

Thereafter, the interior layout device 100 outputs the rendered space and interior information through the indoor structure information interface (S 113), and provides service functions such as space interior experience, interior editing, furniture tagging, furniture information, purchase information, and the like according to a user input with respect to the output space and interior (S115).

Meanwhile, the interior layout device 100 stores and uploads the completed indoor structure information and interior layout information (S117).

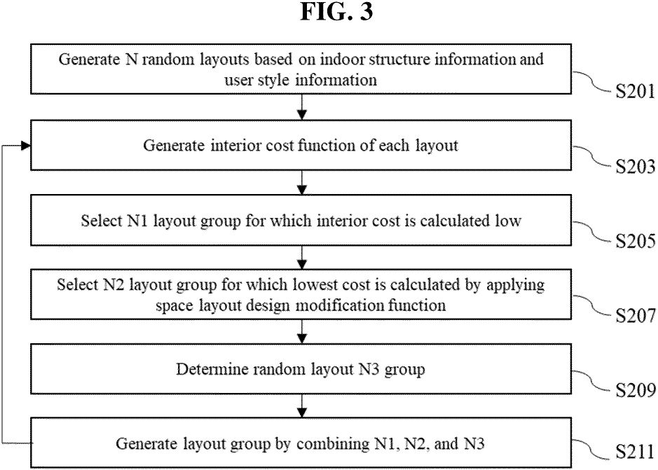

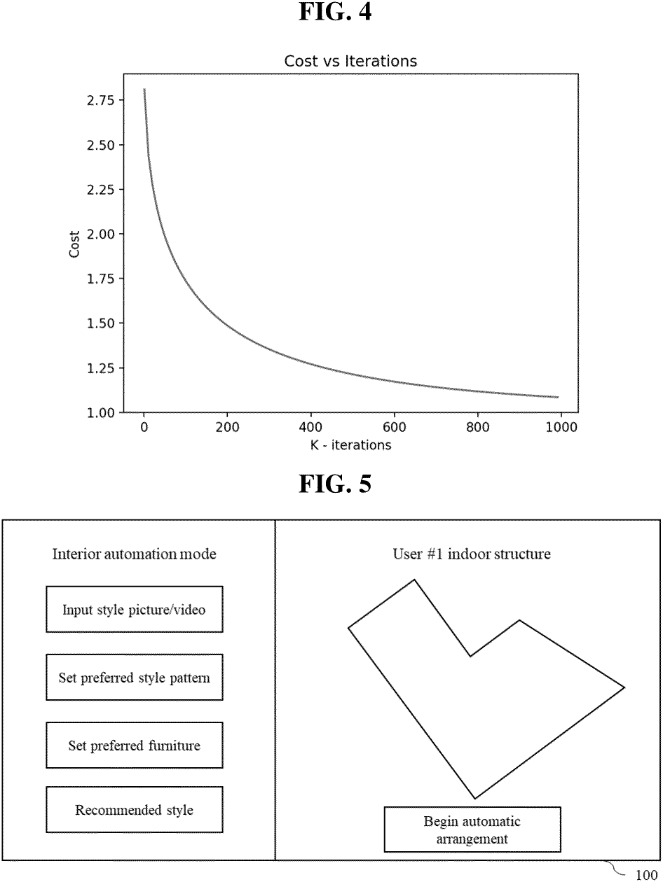

FIG. 3 is a flowchart illustrating an iteration process of generating an interior layout according to an embodiment of the present invention, and FIG. 4 is a view showing cost efficiency with respect to the number of iterations of an iteration process of generating an interior layout according to an embodiment of the present invention.

First, referring to FIG. 3, the interior layout device 100 according to an embodiment of the present invention generates N random layouts based on the indoor structure information and the user style information through the layout generation processing unit 130 (S201).

Then, the interior layout device 100 generates an interior cost function of each layout through the layout generation processing unit 130 (S203).

Here, the interior layout device 100 selects an N1 layout group, for which the interior cost is calculated to be low, through the layout generation processing unit 130 (S205).

Thereafter, the interior layout device 100 selects an N2 layout group, for which the lowest cost is calculated, by applying a space layout design modification function through the layout generation processing unit 130 (S207).

Meanwhile, the interior layout device 100 determines a random layout N3 group using an arbitrary variable through the layout generation processing unit 130 (S209).

Thereafter, the interior layout device 100 generates a layout group by combining the N1, N2, and N3 groups through the layout generation processing unit 130 (S211).

According to the randomness and iteration of the process, the weight value of each layout may be optimized according to formation of a correlation for improving cost, and as function-based N1 and N2 group selection classification is processed for each layout and a new random layout N3 is continuously added according to the optimization, a more appropriate automated layout may be generated.

Here, the size of the generated layout group may be smaller than the initial number of N. N1, N2, and N3 may be determined in proportion to the size of N, and may be limited within a preset maximum size. For example, when N is smaller than or equal to a predetermined size, the sizes of N1, N2, and N3 may be ⅓N, ⅓N, and ⅓N, and when N is greater than or equal to the predetermined size, the sizes of N1, N2, and N3 may be calculated as ⅙N, ⅔N, and ⅙N. The ratio of size of N may be preset according to processing efficiency.

With regard to the processing efficiency, FIG. 4 shows a cost graph in which an optimal layout is generated with respect to the number of iterations K. Accordingly, it is preferable to limit the number of iterations to the number of times of optimizing the preset processing efficiency, as well as within the limit of the space use rate. As shown in FIG. 4, when a layout having an optimal cost is calculated from a layout group N iterated as much as K times, it may be confirmed that the cost efficiency is lowered as the number of iterations increases. Therefore, it is preferable that the iteration process according to an embodiment of the present invention is set not to exceed the space use rate and the preset maximum number of iterations.

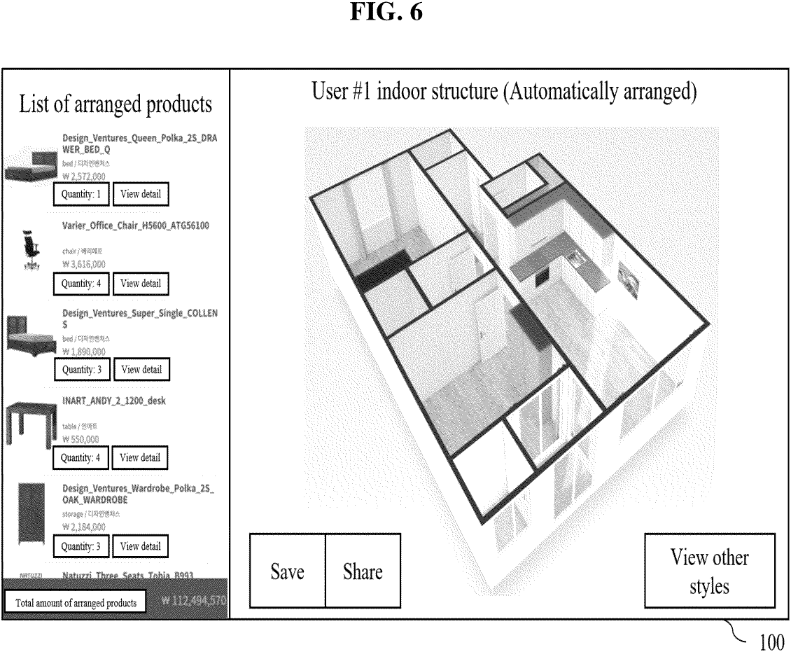

FIGS. 5 and 6 are views showing an indoor structure information interface output from an interior layout device as a method according to an embodiment of the present invention is performed.

Referring to FIG. 5, the interior layout device 100 according to an embodiment of the present invention may provide an interior automation mode corresponding to the indoor structure information of a user through the interface output unit 150. The user may input desired style picture or video information as the style-related information through the input unit 110, set a preferred style pattern, set specific preferred furniture, or receive a randomly recommended style without a separate setting. In addition, the user may begin the style analysis of the style information analysis unit 120 and the layout generation processing of the layout generation processing unit 130 according to an embodiment of the present invention through input of an automatic arrangement button.

In addition, referring to FIG. 6, FIG. 6 is a view for explaining a layout automation result interface generated according to an embodiment of the present invention, and shows that an indoor structure interface, in which space layouts and interiors are automatically arranged, is rendered and output through the interface output unit 150.

As shown in FIG. 6, a user may confirm a list of arranged products, furniture information, and purchase information, select storage or sharing of the indoor structure information on which interior automation is processed, or request again to perform an automation process according to another style. In this way, as a process of interior layout automation on an indoor structure is allowed according to input of various styles by the user, the user may intuitively and conveniently generate space and interior design information without requiring a separate precise design or a professional work of an expert.

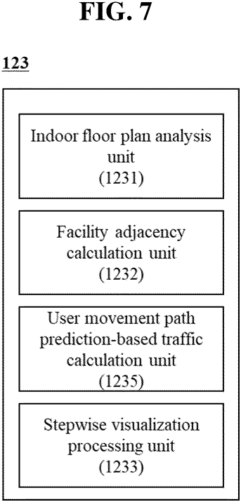

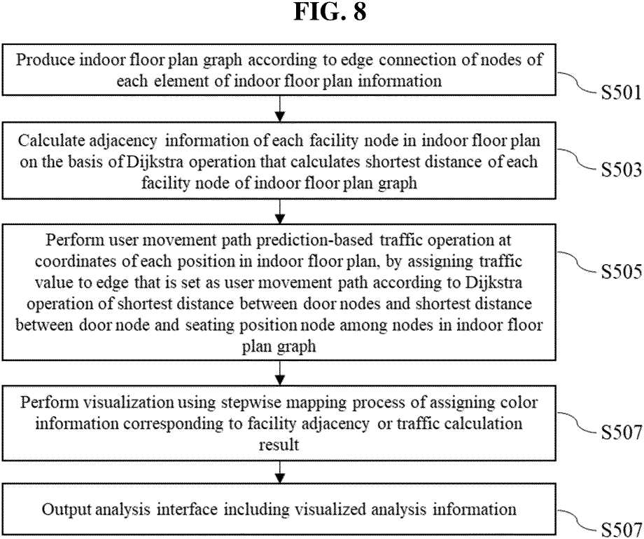

FIG. 7 is a block diagram showing a space use rate analysis unit according to an embodiment of the present invention in more detail.

Referring to FIG. 7, the space use rate analysis unit 123 according to an embodiment of the present invention may perform a space use rate analysis based on the flow of a user on the basis of the indoor structure information and the interior layout information, and visualize and output an analysis result through the interface output unit 150.

To this end, the control unit 140 may control to generate a separate space use rate analysis interface including the analysis information visualized by the space use rate analysis unit 123, and output the space use rate analysis interface through the interface output unit 150.

Here, the visualized analysis information may include, for example, heat map information of each facility area (toilet, exit, elevator, or the like) analyzed from the indoor floor plan information in which interior objects (rooms, openings, furniture, and the like) are arranged.

The heat map information according to an embodiment of the present invention may indicate adjacency information of each facility area to which color information visualized in steps is assigned, or may indicate traffic information based on prediction of a user movement path, to which the color information is assigned. In addition, and as additional information that can be analyzed in the future is added, it may indicate complex relationship information related to each other. For example, the heat map information may indicate complex space use rate analysis information calculated by assigning an arbitrary weight to traffic information and adjacency information as color information visualized in steps.

More specifically, the space use rate analysis unit 123 includes an indoor floor plan analysis unit 1231, a facility adjacency calculation unit 1232, a user movement path prediction-based traffic calculation unit 1235, and a stepwise visualization processing unit 1233.

The indoor floor plan analysis unit 1231 produces an indoor floor plan graph, in which node and edge information of each element is assigned to the indoor floor plan information, by processing an indoor floor plan analysis from the indoor structure information and the interior layout information.

Here, each element may include interior objects (rooms, openings, furniture, and the like) and facility areas (toilets, exits, elevators, and the like), and the edge information may indicate distance information between elements.

More specifically, the indoor floor plan analysis unit 1231 generates an indoor floor plan drawing from the indoor structure information and the interior layout information.

In addition, the indoor floor plan analysis unit 1231 partitions the indoor floor plan drawing into one or more pixel areas, and generates a node at the central position of each pixel area.

In addition, the indoor floor plan analysis unit 1231 may form an edge between adjacent nodes in correspondence to each node, and the edge may be formed not to cross a wall object on the indoor floor plan drawing. A relatively adjacent position between nodes may be identified as top, bottom, left, right, top left, top right, bottom left, or bottom right.

In addition, the indoor floor plan analysis unit 1231 may additionally form a door node at a position corresponding to each door object on the indoor floor plan drawing. Each door node may be connected by an edge to two most adjacent nodes among the nodes of rooms sharing a wall in which the door node is included.

In addition, the indoor floor plan analysis unit 1231 may additionally form a node at each seating position (chair, sofa, or the like) on the indoor floor plan drawing. Each seating position node may be connected by an edge to two nodes most adjacent to the seating position node.

Accordingly, the indoor floor plan analysis unit 1231 includes one or more pixel area nodes, and at least one among a door node and a seating position node, and generates an indoor floor plan graph in which each node is connected by a preset edge.

Then, the facility adjacency calculation unit 1232 calculates spatial adjacency to each facility node on the basis of the indoor floor plan graph.

More specifically, the facility adjacency calculation unit 1232 may set facility nodes, and determine spatial adjacency from an arbitrary location to each facility node according to edge information between nodes. Each node-to-node edge may indicate distance information between nodes, and may indicate spatial adjacency from all points in the indoor floor plan to a node of a specific facility (toilet, meeting room, exit, or the like).

For calculation of the spatial adjacency, the facility adjacency calculation unit 1232 may update an adjacency value of each facility node by assigning an initial adjacency value corresponding to a preset facility node, and performing a Dijkstra operation of calculating the shortest path from each facility node to all other nodes in the indoor floor plan graph.

Here, the Dijkstra operation may include an operation of calculating the shortest path of each facility node to all other nodes on the indoor floor plan graph to which an edge weight is assigned, and may be implemented by performing an iterative comparison operation or processing a heap tree or the like using a priority queue. For example, the facility adjacency calculation unit 1232 may perform an operation of repeatedly updating each shortest distance while sequentially adding facility nodes connected by an edge on the basis of an arbitrary first facility node.

For example, when facility node A is connected to facility node B by an edge, the smallest value among a value, which is obtained by adding a weight of the edge between facility node A and facility node B to the shortest distance value from the starting point to facility node A, and an existing shortest distance value previously assigned to facility node B may be updated as the shortest distance of facility node B.

The facility adjacency calculation unit 1232 may determine a node value determined according to the Dijkstra operation as the adjacency value of each node, and the determined adjacency value may be transmitted to the stepwise visualization processing unit 1233 and assigned with color information in units of pixels. Accordingly, as the adjacency information of indoor nodes is output according to stepwise colors, the user may intuitively and easily confirm results of analyzing adjacency of indoor spaces and facilities.

Meanwhile, the user movement path prediction-based traffic calculation unit 1235 may calculate traffic information according to a degree of movement paths overlapped with each other by simulating movement paths of the user on the indoor floor plan graph. The traffic information may be used to calculate a most frequently used facility or an area of high indoor traffic among the facility nodes, and as the traffic information is output according to stepwise colors through the stepwise visualization processing unit 1233, the user may intuitively and easily confirm results of analyzing indoor traffic.

In the same way, the user movement path prediction-based traffic calculation unit 1235 may perform a user movement path prediction-based traffic calculation process using the Dijkstra method described above.

More specifically, first, the user movement path prediction-based traffic calculation unit 1235 calculates a first shortest path having the shortest distance between all door pairs identified from the indoor floor plan graph.

Then, the user movement path prediction-based traffic calculation unit 1235 calculates a second shortest path having the shortest distance between all door pairs and a seating position.

Then, the user movement path prediction-based traffic calculation unit 1235 adds a preset traffic value to each node positioned on the first shortest path and the second shortest path. The traffic value may be determined according to a preset path type. The path type may include a first path type of connecting a door to a door, a second path type of connecting a door to a seating position, and the like.

By repeatedly performing the user movement path prediction-based traffic calculation process based on the Dijkstra method described above, the user movement path prediction-based traffic calculation unit 1235 may calculate traffic information at each position in the indoor floor plan graph, and the calculated traffic information may be transmitted to the stepwise visualization processing unit 1233 and mapped with color information.

The user movement path prediction-based traffic calculation unit 1235 according to an embodiment of the present invention may set the path type and traffic value described above to allow more accurate traffic calculation. These path types and traffic value may be determined according to a previously learned human behavior model or previously collected behavioral statistical information, and as the amount of learned or collected data increases, more accurate traffic information analysis may be possible.

Meanwhile, as described above, the stepwise visualization processing unit 1233 collects adjacency information transmitted from the facility adjacency calculation unit 1232 or traffic information transmitted from the user movement path prediction-based traffic calculation unit 1235, maps predetermined stepwise color information, and outputs an analysis interface including an indoor floor plan graph mapped with color information through the interface output unit 150.

Accordingly, the stepwise visualization processing unit 1233 may output an indoor floor plan graph showing space use rate analysis information according to mapping of color information, and a user may visually and easily recognize the facility and spatial adjacency or indoor traffic prediction information.

For example, the stepwise visualization processing unit 1233 may map color information such as red in an area of high facility adjacency, blue in an area of low facility adjacency, and the like, or map color information such as red in an area of high indoor traffic, blue in an area of low indoor traffic, and the like, and output an indoor floor plan graph in which color information is mapped in correspondence to all nodes or pixels. Accordingly, the analysis interface may be output in the form of a facility adjacency analysis interface or an indoor traffic analysis interface.

FIG. 8 is a flowchart illustrating the operation of a space use rate analysis unit according to an embodiment of the present invention.

Referring to FIG. 8, first, the space use rate analysis unit 123 according to an embodiment of the present invention produces an indoor floor plan graph according to edge connection of nodes of each element on the indoor floor plan through the indoor floor plan analysis unit 1231 (S501).

Then, the space use rate analysis unit 123 calculates adjacency information of each facility node in the indoor floor plan by repeatedly performing Dijkstra operation that calculates the shortest distance of each facility node included in the indoor floor plan graph through the facility adjacency calculation unit 1232 (S503).

Thereafter, the space use rate analysis unit 123 performs a user movement path prediction-based traffic operation at the coordinates of each position in the indoor floor plan, by assigning a traffic value to an edge that is set as the user movement path according to the Dijkstra operation of the shortest distance between door nodes and the shortest distance between a door node and a seating position node among the nodes on the indoor floor plan graph through the user movement path prediction-based traffic calculation unit 1235 (S505).

Then, the space use rate analysis unit 123 performs visualization using the stepwise mapping process of assigning color information corresponding to the facility adjacency or traffic calculation result through the stepwise visualization processing unit 1233 (S507).

Thereafter, the space use rate analysis unit 123 outputs an analysis interface including the analysis information visualized by the stepwise visualization processing unit 1233 through the interface output unit 150 (S509).

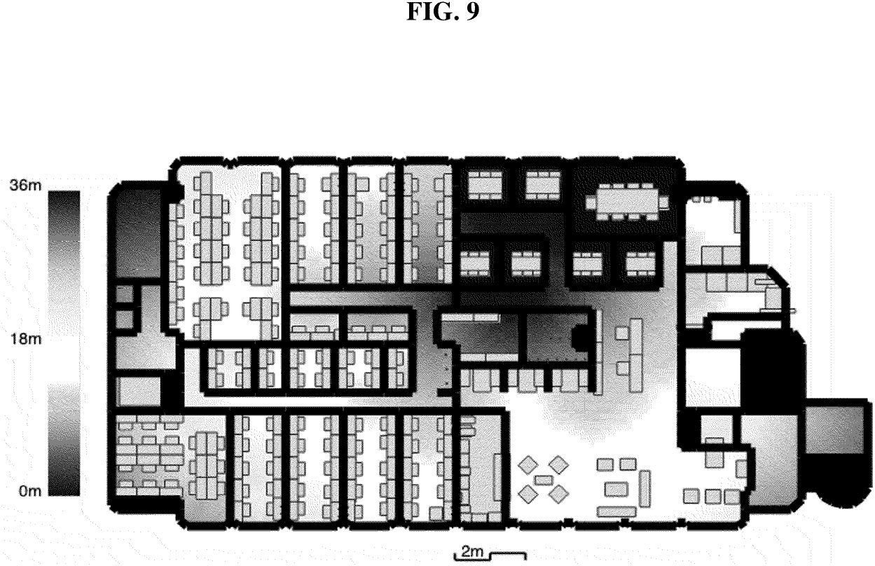

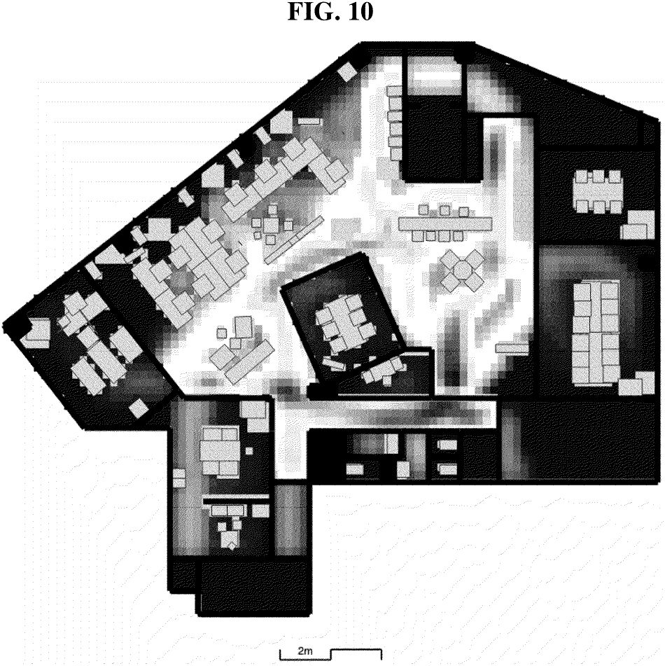

FIGS. 9 to 10 are exemplary views showing an analysis interface including visualized space use rate analysis information according to an embodiment of the present invention.

As shown in FIGS. 9 and 10, the space use rate analysis information according to an embodiment of the present invention may be output through an analysis interface in which color information is mapped according to the coordinates of each position in an indoor floor plan. The color information may be assigned in steps from red to yellow and blue in correspondence to a space use rate analysis value, and the user may confirm the space use rate analysis information very intuitively.

In addition, the space use rate analysis interface may include a facility adjacency analysis interface according to adjacency information calculated by the facility adjacency calculation unit 1232, and an indoor traffic analysis interface according to traffic information calculated by the user movement path prediction-based traffic calculation unit 1235, and these analysis interfaces are shown in FIGS. 9 and 10, respectively.

FIG. 9 is an exemplary view showing a facility adjacency analysis interface calculated according to facility adjacency calculation of the the facility adjacency calculation unit 1232. As shown in FIG. 9, the space use rate analysis unit 123 may identify a facility node corresponding to the position coordinates in each indoor floor plan, map color information to an adjacent value calculated according to each facility node, and output an indoor floor plan including visualized adjacency information.

For example, in FIG. 9, blue facilities having a small value may be interpreted as having good adjacency since the shortest distance value is small, and red facilities having a large value may be interpreted as having poor adjacency since the shortest distance value is large.

In addition, FIG. 10 is an exemplary view showing an indoor traffic analysis interface calculated according to traffic calculation of the user movement path prediction-based traffic calculation unit 1235. As shown in FIG. 10, the space use rate analysis unit 123 may calculate shortest path information based on user behavior in each indoor floor plan, map color information to a traffic value determined in correspondence to each path information, and output an indoor floor plan including visualized traffic information.

For example, in FIG. 10, blue paths having a small value may be interpreted as having low traffic since the shortest distance value is small, and red paths having a large value may be interpreted as having high traffic since the shortest distance value is large.

Accordingly, as a user may be provided with the analysis interfaces shown in FIGS. 9 and 10 and use the interfaces to design an indoor structure more efficiently and effectively or to analyze and change the current indoor structure, the interior layout device 100 according to an embodiment of the present invention may provide a function interface which facilitates understanding of space utilization and a use rate made by spaces and interiors and design of a layout thereof without professional knowledge or an analysis work.

The method according to the present invention described above may be manufactured as a program to be executed on a computer and stored in a computer-readable recording medium, and examples of the computer-readable recording medium include ROM, RAM, CD-ROM, magnetic tapes, floppy disks, optical data storage devices and the like, and also include those implemented in the form of a carrier wave (e.g., transmission through the Internet).

The computer-readable recording medium may be distributed in computer systems connected through a network, so that computer-readable codes may be stored and executed in a distributed manner. In addition, functional programs, codes, and code segments for implementing the method may be easily inferred by the programmers in the art to which the present invention belongs.

In addition, although preferred embodiments of the present invention have been illustrated and described above, the present invention is not limited to the specific embodiments described above, and various modified embodiments can be made by those skilled in the art without departing from the gist of the invention claimed in the claims, and in addition, these modified embodiments should not be individually understood from the spirit or perspective of the present invention.

1. An operation method of an interior layout device, the method comprising the steps of:
obtaining indoor structure information and interior layout information of a user;
obtaining an indoor floor plan graph from the indoor structure information and the interior layout information;
processing a space use rate analysis using the indoor floor plan graph;
generating an analysis interface in which color information is mapped to the indoor floor plan graph according to the space use rate analysis; and
outputting the analysis interface.

2. The method according to claim 1, wherein the step of obtaining an indoor floor plan graph includes the step of generating, from the indoor structure information and the interior layout information, the indoor floor plan graph, in which a corresponding node is assigned to a preset element, and distance information between elements is assigned as edge information between the nodes.

3. The method according to claim 2, wherein the step of obtaining an indoor floor plan graph further includes the step of partitioning an indoor floor plan drawing corresponding to the indoor floor plan graph into one or more pixel areas, and arranging the nodes at a central position of each pixel area.

4. The method according to claim 1, wherein the analysis interface includes heat map information in an indoor floor plan visualized in steps according to the space use rate analysis.

5. The method according to claim 1, wherein the step of processing a space use rate analysis includes a facility adjacency calculation step of calculating spatial adjacency from all coordinates to each facility node on the basis of the indoor floor plan graph.

6. The method according to claim 5, wherein the facility adjacency calculation step includes the step of outputting a shortest path value determined for each facility node as facility adjacency information, by assigning an initial adjacency value corresponding to a preset facility node, and performing a Dijkstra operation of repeatedly updating the shortest path from each facility node to all other nodes in the indoor floor plan graph.

7. The method according to claim 1, wherein the step of processing a space use rate analysis includes the step of performing a user movement path prediction-based traffic calculation on the basis of the indoor floor plan graph.

8. The method according to claim 7, wherein the step of performing a user movement path prediction-based traffic calculation includes the step of calculating traffic information according to a degree of movement paths overlapped with each other, by simulating movement paths of the user on the indoor floor plan graph.

9. The method according to claim 8, wherein the step of calculating traffic information includes the steps of:
calculating a first shortest path having a shortest distance between all door pairs identified from the indoor floor plan graph;
calculating a second shortest path having a shortest distance between all door pairs and a seating position identified from the indoor floor plan graph; and
adding a preset traffic value to each node positioned on the first shortest path and the second shortest path.

10. The method according to claim 9, wherein the traffic value is determined according to a preset path type, and the path type includes at least one among a first path type of connecting a door and a door, and a second path type of connecting a door and a seating position.

11. An interior layout device comprising:
a space use rate analysis unit obtaining indoor structure information and interior layout information of a user, obtaining an indoor floor plan graph from the indoor structure information and the interior layout information, processing a space use rate analysis using the indoor floor plan graph, and generating an analysis interface in which color information is mapped to the indoor floor plan graph according to the space use rate analysis; and
an interface output unit outputting the analysis interface.

12. The device according to claim 11, wherein the space use rate analysis unit includes an indoor floor plan analysis unit for generating, from the indoor structure information and the interior layout information, the indoor floor plan graph, in which a corresponding node is assigned to a preset element, and distance information between elements is assigned as edge information between the nodes.

13. The device according to claim 12, wherein the indoor floor plan analysis unit partitions an indoor floor plan drawing corresponding to the indoor floor plan graph into one or more pixel areas, and arranges the nodes at a central position of each pixel area.

14. The device according to claim 11, wherein the analysis interface includes heat map information in an indoor floor plan visualized in steps according to the space use rate analysis, and the heat map information includes color information indicating at least one among facility adjacency information and user movement path-based traffic information in the indoor floor plan graph.

15. The device according to claim 11, wherein the space use rate analysis unit includes a facility adjacency calculation unit for calculating spatial adjacency from all coordinates to each facility node on the basis of the indoor floor plan graph.

16. The device according to claim 15, wherein the facility adjacency calculation unit outputs a shortest path value determined for each facility node as facility adjacency information, by assigning an initial adjacency value corresponding to a preset facility node, and performing a Dijkstra operation of repeatedly updating the shortest path from each facility node to all other nodes in the indoor floor plan graph.

17. The device according to claim 11, wherein the space use rate analysis unit includes a user movement path prediction-based traffic calculation unit for performing a user movement path prediction-based traffic calculation on the basis of the indoor floor plan graph.

18. The device according to claim 17, wherein the user movement path prediction-based traffic calculation unit calculates traffic information according to a degree of movement paths overlapped with each other, by simulating movement paths of the user on the indoor floor plan graph.

19. The device according to claim 18, wherein the user movement path prediction-based traffic calculation unit calculates a first shortest path having a shortest distance between all door pairs identified from the indoor floor plan graph, calculates a second shortest path having a shortest distance between all door pairs and a seating position identified from the indoor floor plan graph, and adds a preset traffic value to each node positioned on the first shortest path and the second shortest path.

20. The device according to claim 19, wherein the traffic value is determined according to a preset path type, and the path type includes at least one among a first path type of connecting a door and a door, and a second path type of connecting a door and a seating position.
